(19) United States
(12) Patent Application Publication
(10) Pub. No.: US 2002/0006733 A1
(43) Pub. Date: Jan. 17, 2002

(54) Multilayer thin film and its fabrication process as well as electron device

(75) Inventors: Takao Noguchi, Tokyo (JP); Yoshihiko Yano, Tokyo (JP); Hisatoshi Saitou, Tokyo (JP); Hidenori Abe, Tokyo (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: TDK CORPORATION, Tokyo (JP)

(21) Appl. No.: 09/842,802

(22) Filed: Apr. 27, 2001

(30) Foreign Application Priority Data
Apr. 27, 2000 (JP) 2000-128230

(51) Int. Cl. H01L 21/302; H01L 21/461

(52) U.S. Cl. 438/728

(57) ABSTRACT

The invention has for its objects to provide a multilayer thin film including a ferroelectric thin film having much more improved properties on an Si substrate and its fabrication process as well as an electron device comprising the same. This object is achieved by the provision of a multilayer thin film formed on an Si substrate by epitaxial growth, which comprises a buffer layer formed on the Si substrate, which layer includes an oxide thin film, a perovskite oxide thin film formed on the buffer layer, which film has a (100) or (001) orientation, and a ferroelectric thin film epitaxially grown on the perovskite oxide thin film and its fabrication process as well as an electron device comprising the same.

### BACKGROUND OF THE INVENTION

### ART FIELD

The present invention relates to a multilayer thin film including a ferroelectric thin film and its fabrication process as well as an electron device comprising such a multilayer thin film. Typically, the multilayer thin film may be applied to semiconductor memories, thin-film ferroelectric devices such as infrared sensors, recording media for recording information by polarization reversal of ferroelectrics by AFM (atomic force microscope) probes or the like, thin-film vibrators, thin-film VCOs and thin-film filters used for mobile communications equipment, thin-film piezoelectric devices used for liquid injectors or the like.

### BACKGROUND ART

In recent years, electron devices comprising Si substrates that are semiconductor crystal substrates and ferroelectric films formed and packed thereon have been invented, and are now under intensive study. Typical such devices are semiconductor memories such as nonvolatile memories, film bulk acoustic resonators (FBARs), thin-film VCOs and thin-film filters. To allow such electron devices to have the optimum device performance and reproducibility, there is an increasing demand for epitaxial films as close to perfect single crystals as possible for the reason that with polycrystal materials, it is difficult to obtain satisfactory device performance due to physical quantity disturbances by grain boundaries. Since most of current ferroelectric materials have their polarization axes in the [001] direction, epitaxially grown ferroelectric films should preferably have (001) orientations to obtain improved ferroelectric properties.

Typical ferroelectric thin films include those of perovskite oxides such as PbTiO₃, PZT and BaTiO₃. The inventors have already filed a patent application (JP-A 09-110592) to come up with a process for achieving an easy epitaxial growth of these perovskite oxide thin films on Si single crystal substrates.

Of these ferroelectric thin films, PZT is one of materials showing great promise for applications to various electron devices by epitaxial growth on Si, because PZT has preferable ferroelectric properties, and excellent piezoelectric properties as well.

So far, some attempts have been made to form PZT on Si substrates primarily in the form of films having (101), (111) and other orientations or polycrystal films. In other words, it is still very difficult to form a PZT film on an Si substrate by epitaxial growth.

With the current state of the art, the inventors have showed processes for an epitaixal growth of ferroelectric thin films such as PZT thin films having the (001) orientation on Si (100) substrates, as set forth in the aforesaid JP-A 09-110592 as well as in JP-A's 10-223476, 11-26296, etc.

As a result of study after study of these epitaxially grown PZT or other ferroelectric thin films and electron devices using the same, the inventors have found that ferroelectric films having much more improved properties can be obtained if a perovskite oxide thin film such as a PbTiO₃ thin film is first epitaxially grown on an Si (100) substrate, and a ferroelectric film such as a PZT film is then epitaxially grown on the perovskite oxide thin film.

Until now there has been known a structure where PZT or other ferroelectric material is formed on a PbTiO₃ or other layer provided underneath PZT or other ferroelectric material.

For instance, JP-A 06-57411 discloses a structure wherein an electrically conductive coating such as a Pt coating is formed on an Si or other substrate with a buffer layer of Ti or the like interposed therebetween, a primer dielectric layer is formed by sputtering on the conductive coating, and a perovskite oxide dielectric layer is formed by sputtering on the primer dielectric layer, and shows that this structure provides a dielectric thin film having high crystallographic properties with limited pinholes. JP-A 06-290983 discloses a dielectric thin film having a multilayer structure comprising a perovskite dielectric film free from Zr and a perovskite dielectric film containing Zr, and shows that this dielectric thin film can be fabricated at a substrate temperature of 500° C. or lower. JP-A 07-99252 discloses a fabrication process comprising the steps of forming a lead titanate film on a substrate and forming a lead zirconate-titanate film thereon as well as a semiconductor device, and shows that when the PZT thin film is formed by a sol-gel process, the pyrochlore-to-perovskite phase transition temperature can be lowered by 100° C. JP-A 06-89986 discloses a structure wherein a primary insulating layer of PZT or the like is in contact with a subordinate insulating layer of PbTiO₃ or the like, and shows that when a polycrystal ferroelectric film is fabricated by MOCVD, it is possible to obtain a ferroelectric film having improved crystallographic properties with limited leakage.

All the foregoing are the examples of polycrystal films. In general, when ferroelectric films are formed on polycrystal electrodes, it is difficult to obtain films of good crystallographic properties. In such cases, it is believed that by forming a ferroelectric film of PZT or the like on a primer layer of PbTiO₃ or the like, the crystallization of PZT may be promoted to lower the crystallization or formation temperature and improve the crystallographic properties. This is because PbTiO₃ is more likely to create a perovskite nucleus than PZT.

On the other hand, examples of the primer layers of PbTiO₃ or the like for epitaxial films on substrates have been described in the following publications. JP-A 07-172984 discloses in the example that an initial layer of a PLT thin film and a main deposition layer of a PZT thin film are formed on Pt provided on MgO. Since the PLT initial layer is described as being a nearly perfect epitaxial film, the PZT main deposition layer thereon must be an epitaxial film or a crystalline film close thereto. This publication asserts that by the formation of the PLT initial layer, PZT can be formed at a temperature lower by 50° C. than that in the absence of any initial layer. JP-A 07-193135 discloses a structure wherein a perovskite ferroelectric thin film composed mainly of Pb and Ti is formed as the first layer on a GaAS substrate and a perovskite ferroelectric thin film composed mainly of Pb, Ti and Zr is formed as the second layer thereon. The publication asserts in the example that the c-axis oriented thin film of PZT or PLZT having difficulty in the formation of a thin film of good crystallographic properties can be obtained by forming PLT on a GaAs (100) substrate as the first layer and forming PZT as the second layer thereon.

Thus, there are some examples of the primer layer of PbTiO₃ or the like for epitaxial films on substrates. However, never until now is there any example of the primer layer for an epitaxially grown ferroelectric film on an Si substrate. When a ferroelectric film is epitaxially grown on an Si substrate by the processes set forth in JP-A 09-110592 published under the name of the applicant as well as JP-A's 10-223476 and 11-26296, an epitaxial film of nearly perfect crystallographic properties can be obtained without recourse to the formation of a primer layer of PbTiO₃ or the like, because the ferroelectric film is deposited while, from the beginning, perovskite structure crystals are in alignment with the atomic arrangement of crystals on the surface of the substrate. With regard to the epitaxial film on the Si substrate, the fact that the ferroelectric thin film formed using a primer layer of a perovskite oxide such as PbTiO₃ has properties much superior to those in the absence of such a primer layer has been discovered for the first time in the present invention.

### SUMMARY OF THE INVENTION

One object of the invention is to provide a multilayer thin film including a ferroelectric thin film having much more improved properties on an Si substrate and its fabrication process as well as an electron device comprising the same.

Another object of the invention is to use a multilayer thin film including a ferroelectric thin film having improved properties according to the invention and formed on an Si single crystal substrate that is a semiconductor substrate, thereby providing thin-film vibrators, thin-film VCOs and thin-film filters used for mobile communications equipment, thin-film piezoelectric devices used for liquid injectors, etc., semiconductor memories, thin-film ferroelectric devices such as infrared sensors, recording media for recording information by polarization reversal of ferroelectrics as by AFT (atomic force microscope) probes, and so on.

Such objects are attained by the following embodiments (1) to (7) of the invention.

(1) A multilayer thin film formed on an Si substrate by epitaxial growth, which comprises:

a buffer layer formed on said Si substrate, which layer includes an oxide thin film,

a perovskite oxide thin film formed on said buffer layer, which film has a (100) or (001) orientation, and

a ferroelectric thin film epitaxially grown on said perovskite oxide thin film.

(2) The multilayer thin film of (1) above, wherein said perovskite oxide thin film has insulating properties.

(3) The multilayer thin film of (1) or (2) above, which has an electrically conductive thin film between said perovskite oxide thin film and said oxide thin film in said buffer layer.

(4) The multilayer thin film of anyone of (1) to (3) above, wherein said perovskite oxide thin film comprises PbTiO₃.

(5) The multilayer thin film of any one of (1) to (4) above, wherein said ferroelectric oxide thin film comprises PZT.

(6) An electron device comprising a multilayer thin film as recited in any one of (1) to (5) above.

(7) A multilayer thin film fabrication process by:

forming a buffer layer including an oxide thin film on an Si (100) substrate,

epitaxially growing a perovskite oxide thin film having a (100) or (001) orientation on said buffer layer, and

epitaxially growing a ferroelectric thin film on said perovskite oxide thin film.

### ACTION

As a result of study after study of a multilayer thin film comprising an epitaxially grown ferroelectric thin film on an Si substrate, especially the ferroelectric thin film, and an electron device using this ferroelectric thin film, the inventors have found that ferroelectric films having much more improved properties can be obtained if a perovskite oxide thin film such as a PbTiO₃ thin film is first epitaxially grown on an Si (100) substrate, and a ferroelectric film such as a PZT film is then epitaxially grown on the perovskite oxide thin film.

It has also been found that the multilayer thin film including a ferroelectric thin film having improved properties according to the invention and formed on an Si single crystal substrate that is a semiconductor substrate can very advantageously be applied to various fields inclusive of thin-film vibrators, thin-film VCOs and thin-film filters used for mobile communications equipment, thin-film piezoelectric devices used for liquid injectors, etc., semiconductor memories, thin-film ferroelectric devices such as infrared sensors, and recording media for recording information by polarization reversal of ferroelectrics as by AFT (atomic force microscope) probes.

### BRIEF EXPLANATION OF THE DRAWINGS

FIG. 1 is illustrative of one example of the evaporation system used to form the multilayer thin film according to the invention.

FIG. 2 is a drawing substitute photograph illustrative of a crystal structure, wherein an RHEED image of a ZrO₂ thin formed on an Si single crystal substrate is shown.

FIG. 3 is a drawing substitute photograph illustrative of a crystal structure, which shows an RHEED image of a Y₂O₃ thin film formed on the ZrO₂ thin film whose RHEED image is shown in FIG. 2.

FIG. 4 is a drawing substitute photograph illustrative of a crystal structure, which shows an RHEED image of a Pt thin film formed on the Y₂O₃ thin film whose RHEED image is shown in FIG. 3.

FIG. 5 is a drawing substitute photograph illustrative of a crystal structure, which shows an RHEED image of an PbTiO₃ thin film formed on the Pt thin film whose RHEED image is shown in FIG. 4.

FIG. 6 is a drawing substitute photograph illustrative of a crystal structure, which shows an RHEED image of a PZT thin film formed on the PbTiO₃ thin film whose RHEED image is shown in FIG. 5.

FIG. 7 is an X-ray diffraction chart for a multilayer thin having a PZT/PbTiO₃/Pt/Y₂O₃/ZrO₂/Si (100) structure.

FIG. 8 is a structural representation of an FBAR device fabricated using the multilayer thin film of the invention.

### EXPLANATION OF THE PREFERRED EMBODIMENTS

In the multilayer thin film according to the present invention, an epitaxially grown perovskite oxide thin film having a (100) or (001) orientation is formed on an Si substrate with a buffer layer interposed between them, and an epitaxially grown ferroelectric thin film is formed on the perovskite oxide film.

Herein, that a thin film has the (001) orientation, for instance, is understood to mean that the (001) plane is present substantially parallel with a film plane.

The “uniaxially oriented film” used herein is understood to refer to a crystallized film wherein the desired crystal planes line up parallel with the surface of the substrate. To be more specific, the uniaxially oriented film means a film in which, as measured by X-ray diffraction (XRD), the reflection peak intensity of a plane other than the desired one is up to 10%, preferably up to 5% of the maximum peak intensity of the desired plane. In the (00L) uniaxially oriented film, typically, the c-plane uniaxially oriented film, the reflection intensity of a plane other than the (00L) plane is up to 10%, preferably up to 5% of the reflection maximum peak intensity of the (00L) plane, as measured by 2θ-θ X-ray diffraction. It is herein appreciated that (00L) is a general notation for the (001) series of planes, viz., equivalent planes such as (001) and (002).

First of all, the epitaxial film used herein must be such a uniaxially oriented film as mentioned above. The second condition for the epitaxial film used herein is that when a film plane is defined by an x-y plane and a film thickness direction is defined by a z-axis, all crystals line up in alignment with the x-, y-and z-axis directions. The presence of such orientations may be ascertained by a spot or streak form of sharp pattern as evaluated by RHEED. For instance, when there are disturbances in the crystal orientations on the buffer layer having surface asperities, a RHEED image does not exhibit any sharp spot, and tends to elongate in a ring form. A certain thin film, if it satisfies the aforesaid two conditions, can then be thought of as an epitaxial film.

The “epitaxially grown film” used herein is understood to include not only an epitaxial film but also a thin film that is an epitaxial film in the growth process but has a domain structure at room temperature. A tetragonal perovskite oxide thin film such as a PZT thin film grows in the form of a cubic (100) epitaxial film at a growth temperature; however, this cubic phase is transited to a tetragonal phase in the post-growth cooling process, yielding a 90° domain structure film with the (100) orientation coexisting with the (001) orientation.

Some embodiments of the invention are now explained in detail.

Buffer Layer

The buffer layer used herein is an oxide single layer or a mutilayer comprising a plurality of oxides. Alternatively, the buffer layer may include an electrically conductive thin film stacked on the oxide or oxides. The buffer layer is interposed between the perovskite oxide and the substrate to take a role in the high-quality epitaxial growth of the perovskite oxide on the Si substrate. Further, this buffer layer functions as both an insulator and an etching stopper layer during via hole etching for FBAR devices, etc. The buffer layer with the conductive thin film stacked thereon also serves as an electrode. If a ferroelectric thin film is formed on the conductive thin film, it is then possible to achieve various electron devices having satisfactory properties, e.g., thin-film bulk resonators.

To obtain a ferroelectric thin film of good-enough crystallographic properties, it is required to form the buffer layer in the form of an epitaxial film close to a single crystal. To meet such requirements, it is preferable to use a process as set forth in JP-A 09-110592 published under the names of the applicant et al., viz., a process wherein a layer including a ZrO₂ thin film having the (001) orientation, a stabilized zirconia thin film, a rare earth element oxide thin film, etc. is formed on an Si single crystal substrate, a perovskite layer comprising BaTiO₃, etc. and having the (001) orientation is formed on the layer, and an electrically conductive thin film comprising Pt, etc. is formed on the perovskite layer. The reason for the provision of the perovskite layer is that when the Pt thin film is formed directly on the ZrO₂ (001) thin film, Pt has the (111) orientation or assumes a polycrystal form and so fails to yield any Pt (100) uniaxially oriented film. This is because for the reason of large lattice mismatching between the ZrO₂ (001) plane and the Pt (100) plane, Pt grows using the energetically stable (111) plane as a growth plane rather than grows epitaxially, i.e., using the (100) plane as a growth plane.

For the buffer layer, it is acceptable to use a multilayer thin film as set forth in JP-A 11-312801. For the multilayer thin film disclosed in this publication, it is unnecessary to form a multi-composition perovskite thin film such as a BaTiO₃ thin film, because the conductive thin film has already been formed on the buffer layer having facets. For this reason, it is possible to fabricate an epitaxial conductive thin film of good-enough crystallographic properties in a much easier manner. The buffer layer set forth in the aforesaid publication is characterized in that its interface with the conductive thin film includes the {111} facet plane. This buffer layer is an epitaxial film having the cubic (100) orientation, the tetragonal (001) orientation or the orthorhombic (001) orientation and, hence, its facet plane is the {111} facet plane. The conductive thin film grows epitaxially in the form of the {111} oriented film on the {111} facet plane of the buffer layer. As the conductive thin film grows, the pits defined by facet planes are filled up. Eventually, the surface of the conductive thin film becomes flat and parallel with the surface of the substrate. Although this surface provides the cubic (100) plane, yet it sometimes provides the tetragonal (001) plane depending on distortion, etc. of crystal lattices.

The electrically conductive thin film formed on the surface of the buffer layer, on which the facet planes are present, grows while the pits defined by the facet planes are filled up, as mentioned above. Eventually, the surface of the conductive thin film becomes flat and parallel with the surface of the substrate.

Usually, the electrically conductive thin film is in the form of a cubic epitaxial film with the (100) plane oriented parallel with the surface of the film. However, this conductive thin film is sometimes in the form of an epitaxial film having typically the tetragonal (001) orientation, which may occur by deformation of crystals due to stresses.

The electrically conductive thin film should comprise as a primary component preferably at least one of Pt, Ir, Pd, Rh and Au, and should preferably be composed of a pure form of such metals or an alloy containing them. The conductive thin film may be a multilayer thin film defined by two or more thin films having different compositions, or a multilayer thin film defined by a metal thin film and an electrically conductive oxide thin film. Such a multilayer thin film may further comprise an insulting thin film between the respective conductive thin films.

The electrically conductive thin film may effectively apply an electric field to functional thin films formed thereon, e.g., the ferroelectric thin film.

The electrically conductive thin film should have a thickness of preferably 10 to 500 nm, and more preferably 50 to 200 nm. At too small a thickness, the crystallographic properties and surface properties of the conductive thin film are impaired as well. At too large a thickness, the resonance properties of the conductive thin film are impaired when it is used for a piezoelectric device such as an FBAR. When the buffer layer with the surface composed of facet planes is used, sufficient surface flatness is achievable by using a conductive thin film of preferably 30 nm or more, and especially 100 nm or more in thickness to fill up the surface asperities of the buffer layer. To allow the conductive thin film to function well as an electrode, the conductive thin film should preferably have a thickness of 50 to 500 nm.

The electrically conductive thin film should have a specific resistance of preferably 10⁻⁷ to 10³ Ωcm, and more preferably 10⁻⁷ to 10⁻² Ωcm. It is here noted that in the process of buffer layer formation, an SiO₂ layer may possibly occur between the buffer layer and the Si substrate. However, this SiO₂ layer is regarded as being formed by the oxidization of the surface of Si after the buffer layer starts to grow epitaxially and, hence, does not inhibit the epitaxial growth of the buffer layer. Thus, the presence of this SiO₂ layer is acceptable.

Perovskite Oxide Thin Film

The perovskite oxide thin film is formed on and in contact with the buffer layer.

To better the crystallographic properties of the overlying ferroelectric thin film, the perovskite oxide thin film should be grown epitaxially with respect to the buffer layer. The perovskite oxide thin film, if it is a cubic crystal system, should preferably be a (100) uniaxially oriented film. The perovskite oxide thin film of a tetragonal crystal system may have a 90° domain structure with the (100) and (001) orientations due to stresses from the Si substrate, although it should preferably be a (001) uniaxially oriented film.

The perovskite oxide thin film should preferably have insulating properties. The perovskite oxide thin film should have a specific resistance of preferably 10³ Ωcm or greater, and more preferably of about 10⁶ to 10¹² Ωcm.

Preferable materials for the perovskite oxide thin film are BaTiO₃, PbTiO₃, and lead titanate containing a rare earth element, although PbTiO₃ is most preferred. The use of PbTiO₃ enables a Pb-base ferroelectric thin film such as a PZT thin film to be easily formed on the perovskite oxide thin film.

The thickness of the perovskite oxide thin film should preferably be reduced to such an degree that the ferroelectric thin film formed thereon does not malfunction; however, too thin a perovskite oxide thin film fails to produce its own effect. The perovskite oxide thin film should have a thickness of preferably 5 to 100 nm, and more preferably 10 to 50 nm.

Ferroelectric Thin Film

The ferroelectric thin film is provided on the perovskite oxide thin film. Depending on the functions demanded such as ferroelectric properties and piezoelectric properties, an appropriate selection may be made from suitable materials. However, it is preferable to use the following materials. (A) Perovskite materials such as Pb-base perovskite compounds, e.g., lead titanate containing rare earth elements, PZT (lead zirconate-titanate) and PLZT (lanthanum doped lead zirconate-titanate), and Bi-base perovskite compounds, which may be used in simple, composite or laminar forms.

Throughout the present disclosure, the ratio x for O in ABOₓ such as PbTiO₃ is consistently described as 3; however, x is not limited to 3. Some perovskite materials exist in the form of a stable perovskite structure with oxygen deficiencies or in excess of oxygen. Accordingly, the value of x in ABOₓ is usually of the order of 2.7 to 3.3. Further, A/B is not limited to 1. By varying A/B, it is possible to alter electric properties such as ferroelectric and piezoelectric properties, surface flatness, and crystallographic properties. It is thus acceptable to vary A/B depending on the properties necessary for the ferroelectric thin film. Usually, A/B is of the order of 0.8 to 1.3. In this regard, A/B may be found by X-ray fluorescence analysis.

The aforesaid PZT is a solid solution based on PbZrO₃-PbTiO₃. The aforesaid PLZT is a compound wherein PZT is doped with La which, according to ABO₃ notation, is typically represented as (Pb: 0.89˜0.91, La: 0.11˜0.09)(Zr: 0.65, Ti: 0.35)O₃.

Of the perovskite ferroelectric materials, PZT is preferred because of being improved in not only ferroelectric properties but piezoelectric properties as well. A PZT thin film should have a composition wherein the Ti/(Ti+Zr) atomic ratio is in the range of preferably 0.60 to 0.90, and more preferably 0.70 to 0.85. In a composition region wherein the proportion of Ti is less than 0.60, the ferroelectric properties or resonance properties become worse. On the other hand, when the proportion of Ti is too high, insulating properties become worse.

For the rare earth element-containing lead titanate, it is preferable to use compositions wherein the atomic ratio is (Pb+R)/Ti=0.8 to 1.3 and Pb/(Pb+R)=0.5 to 0.99, and especially (Pb+R)/Ti=0.9 to 1.2 and Pb/(Pb+R)=0.7 to 0.97. The rare earth element—containing lead titanate having such compositions is disclosed in JP-A 10-17394.

(B) Tungsten bronze materials such as tungsten bronze oxides, e.g., SBN (strontium-barium niobate) and PBN (lead-barium niobate).

For the tungsten bronze materials, preference is given to those described in A Collection of Ferroelectric Materials, Landoit-Borenstein. Vol. 16. To be more specific, preference is given to (Ba, Sr)Nb₂O₆, (Ba, Pb)Nb₂O₆, PbNb₂O₆, PbTa₂O₆, BaTa₂O₆, PbNb₄O₁₁, PbNb₂O₆, SrNb₂O₆, BaNb₂O₆, etc., or their solid solutions. In particular, SBN[(Ba, Sr)Nb₂O₆] and PBN[(Ba, Pb)Nb₂O₆] are preferred.

The ferroelectric thin film must have grown epitaxially on the underlying perovskite oxide thin film. The ferroelectric thin film, if it is a tetragonal crystal system, should preferably be a (001) uniaxially oriented film. However, this ferroelectric thin film may have a 90° domain structure comprising (100) oriented crystals and (001) oriented crystals under the influence of stresses from the Si substrate.

Fabrication Process

No particular limitation is placed on how to fabricate the buffer layer, perovskite oxide thin film and ferroelectric thin film, and so an appropriate selection may be made from processes capable of allowing epitaxial growth of them on the Si single crystal substrate. However, it is preferable to make use of evaporation processes, and especially those set forth in the aforesaid JP-A 09-110592, and JP-A 10-287494 published under the name of the applicant, etc.

For a specific fabrication process of the invention, how to form a multilayer thin film using a buffer layer comprising a multilayer structure having a stabilized zirconia thin film and a Pt thin film, a perovskite oxide thin film comprising PbTiO₃ and a ferroelectric thin film comprising PZT is now explained.

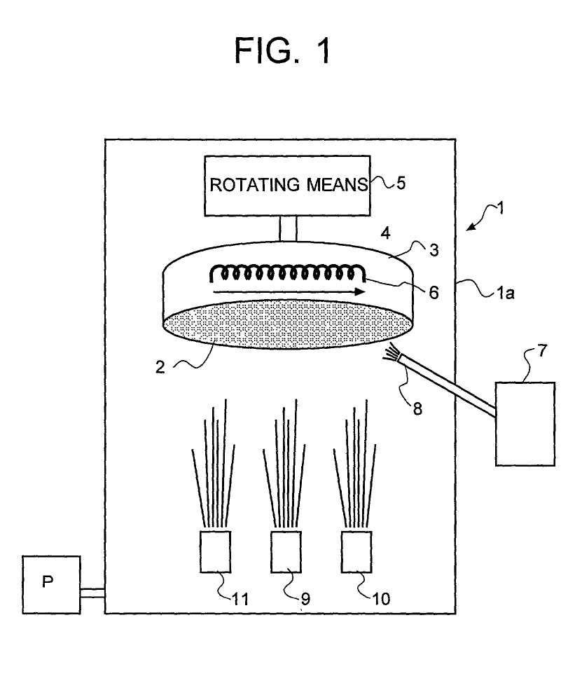

To carry out this fabrication process, it is desired to make use of an evaporation system 1 having such construction as shown in FIG. 1 as an example.

This evaporation system 1 is built up of a vacuum chamber la provided with a vacuum pump P, in which chamber la a holder 3 for holding a substrate 2 on its lower side is provided. This holder 3 is connected to a rotating means 5 such as a motor via a rotary shaft 4, so that it can be rotated by this rotating means 5 to rotate the substrate 2 within its plane. The holder 3 also includes a built-in heating means 6 such as a heater for heating the substrate 2.

The evaporation system 1 includes an oxidizing gas feed unit 7 having an oxidizing gas inlet 8 positioned just beneath the holder 3, whereby the partial pressure of the oxidizing gas can be elevated in the vicinity of the substrate 2. At positions below and further away from the holder 3, there are located a first evaporation unit 9 for feeding Zr or the like, a second evaporation unit 10 for feeding TiOₓ (x=1.67) or the like and a third evaporation unit 11 for feeding PbO or the like. At each evaporation unit, an energy feeder (an electron beam generator, a resistive heater or the like) for supplying energy for evaporation is located together with its own evaporation source.

First of all, the substrate is set at the aforesaid holder. With this fabrication process, it is possible to form homogeneous thin films on a substrate having a large area of typically 10 cm² or larger. This enables an electron device comprising the multilayer thin film of the invention to be fabricated at much lower costs than could be achieved so far in the art. It is here noted that the upper limit to the area of the substrate is about 400 cm² at the bast under the current circumstances, although there is no particular limitation thereon. It is also possible to form the multilayer thin film on a selected region of a wafer using a mask or the like, not all over the surface of the wafer.

Prior to the formation of the buffer layer, it is preferable to subject the Si substrate to surface treatment. For this surface treatment, it is preferable to make use of treating processes as typically disclosed in the aforesaid JP-A 09-110592 or JP-A 10-287494.

After such surface treatment, the Si crystals on the substrate surface are covered and protected by an Si oxide layer. This Si oxide layer is reduced and removed by a metal such as Zr fed onto the substrate surface for the formation of the buffer layer.

Then, the buffer layer is formed. The formation of the buffer layer comprising a multilayer structure having the stabilized zirconia and Pt should preferably be carried out using a fabrication process as set forth in JP-A 11-312801. For the formation of a buffer layer comprising other structure, too, it is preferable to make use of fabrication processes as typically set forth in JP-A's 11-312801 and 9-110592.

The formation of the perovskite oxide thin film should preferably be carried out using a process as typically set forth in the aforesaid JP-A 09-110592. For the formation of PbTiO₃, the substrate should be set at a temperature of preferably 500 to 750° C., and more preferably 550 to 650° C. At too low a substrate temperature, it is difficult to obtain any film of high crystallographic properties, and at too high a substrate temperature, composition variations are likely to occur by re-evaporation or surface asperities of the film tend to become large. In this regard, it is possible to reduce the re-evaporation of material by introducing a slight amount of oxygen radicals into the vacuum chamber during evaporation. For instance, this is effective to inhibit the re-evaporation of Pb or PbO from the PbTiO₃ thin film.

When the a-axis lattice constant of the material used for the perovskite oxide thin film is smaller than the a-axis lattice constant of the material used for the ferroelectric thin film formed thereon, the ferroelectric film can be elongated in the c-axis direction by making use of the elastic distortion due to the misfit. It is thus possible to obtain a ferroelectric film (001) oriented from the interface between the perovskite oxide thin film and the ferroelectric thin film to a thickness of several tens of nanometers.

Then, the ferroelectric thin film is formed by an unheard-of process for providing an epitaxial growth of a ferroelectric thin film such as a PZT thin film on PbTiO₃ epitaxially grown on the Si substrate. This process is for the first time discovered by the present invention. In what follows, this process is explained in detail with reference to the case where PZT is formed as the ferroelectric thin film.

The formation of the PZT thin film on the perovskite oxide thin film should preferably be carried out by feeding PbO, TiOₓ (x=1.67) and Zr from their respective evaporation sources with the introduction of the oxidizing gas. For the oxidizing gas, oxygen, ozone, atomic oxygen, NO₂, radical oxygen or the like may be used. However, it is preferable to use radicalized oxygen for a partial or substantial portion of the oxidizing gas. This makes it possible to inhibit the re-evaporation of Pb or PbO during the formation of the PZT thin film. The reason for using PbO for the lead evaporation source is that PbO is less susceptible to re-evaporation on a high temperature substrate, and higher in the rate of deposition, than Pb. The reason for using TiOₓ for the titanium evaporation source is again that the rate of deposition becomes high. It is not preferable to use Ti in place of Tiₓ because PbO is deprived of oxygen by Ti, yielding Pb susceptible to re-evaporation. The range of x in Tiₓ should be preferably 1≦×<1.9, more preferably 1≦×<1.8, even more preferably 1.5≦×≦1.75, and most preferably 1.66≦₁₃ ×≦1.75. Such Tiₓ. melts in the vacuum chamber with the application of thermal energy thereto, ensuring a stable rate of evaporation.

The substrate temperature for PZT formation should be in the range of preferably 500 to 650° C., and the deposition rate should be in the range of preferably 0.050 to 1.000 nm/s, and more preferably 0.100 to 0.500 nm/s. At too slow a deposition rate, difficulty is involved in keeping the deposition rate constant, and so the film tends to become inhomogeneous. At too high a deposition rate, on the other hand, the crystallographic properties of the film becomes worse.

TiOₓ and Zr should preferably be fed onto the substrate at the rate of evaporation corresponding to the end composition ratio, because nearly the entire amount of Tiₓ and Zr fed is incorporated in the growing PZT crystals. However, composition control of PbO is difficult because PbO is susceptible to composition variations due to its high vapor pressure. In the present formation process that rather makes use of this nature of PbO, the amount of PbO fed from the PbO evaporation source onto the substrate should be in excess of the amount of the PZT film crystals to be formed. Regarding to what degree PbO is fed in excess, here let E[Pb/(Ti+Zr)] represent the atomic ratio of Pb and (Ti+Zr) fed from the evaporation sources, i.e., Pb/(Ti+Zr) and F[Pb/(Ti+Zr)] represent the atomic ratio of Pb and (Ti+Zr) in the formed ferroelectric thin film, i.e., Pb/(Ti+Zr). Then, these relations must be E[Pb/(Ti+Zr)]/F[Pb/(Ti+Zr) ] =1.5 to 3.5, preferably E[Pb/(Ti+Zr)]/F[Pb/(Ti+Zr)]=1.7 to 2.5, and more preferably E[Pb/(Ti+Zr)]/F[Pb/(Ti+Zr) ]=1.9 to 2.3. An excessive portion of PbO or a portion of PbO that is not incorporated in the perovskite structure is re-evaporated on the surface of the substrate, so that only the PZT film of the perovskite structure is grown on the substrate. When E [Pb/(Ti+Zr)]/F[Pb/(Ti+Zr)] is too small, it is difficult to feed a sufficient amount of Pb into the film, and so the film does not take any perovskite structure of high crystallographic properties because the Pb/(Ti+Zr) ratio in the film becomes too low. When E[Pb/(Ti+Zr)]/F[Pb/(Ti+Zr)] is too large, on the other hand, the Pb/(Ti+Zr) ratio in the film becomes too high to obtain any perovskite single-phase structure because other Pb-enriched phases occur in addition to the perovskite phase.

As explained above, PbO and TiOₓ are used as the evaporation sources to enhance the rate of deposition, radical oxygen is used for strong oxidization, and the substrate temperature is set in the given range, so that substantially stoichiometric PZT crystals containing Pb reasonably can be grown on the substrate in a self-alignment manner. This process makes a breakthrough in the fabrication of stoichiometric lead base perovskite crystal thin films and, hence, ferroelectric thin films of extremely high crystallographic properties.

When the thin film is formed on an area of about 10 cm² or greater, for instance, on the surface of a substrate of 2 inches in diameter, the substrate is rotated as shown in FIG. 1 to feed the oxidizing gas uniformly all over the surface of the substrate, thereby accelerating the oxidization reaction all over the surface of the substrate. It is thus possible to form a homogeneous film having a large area. In this case, the substrate should be rotated at 10 rpm or greater. A low rpm makes the distribution of film thickness likely to occur within the plane of the substrate. Although there is no particular upper limit to the rpm of the substrate, the upper limit should usually be about 120 rpm in consideration of the mechanism of the vacuum system used.

The process for the formation of the ferroelectric thin film according to the invention has been described in details. As can be clearly understood from comparisons with conventional vacuum evaporation, sputtering, and laser abrasion processes, this process can be carried out under easy-to-control operating conditions where there is no risk of inclusion of impurities whatsoever, and so lends itself well to obtaining the end product of high integrity with high reproducibility yet with a large area.

In addition, even when this process is used with an MBE system, it is possible to obtain the end product much in the same manner as mentioned above.

The process for the formation of the PZT thin film has been described. This process may be applicable, with the same effects, to the formation of thin films comprising other Pb base ferroelectric materials, and to the formation of Bi base oxide thin films as well. In conventional Bi base oxide thin films, too, composition control has so far been less than satisfactory because of high Bi vapor pressure in a vacuum. In this regard, it has been shown that the Bi base oxide thin films can be formed by this process using Bi₂O₃ evaporation sources instead of PbO evaporation sources. In the Bi base oxide thin films, too, it is possible to obtain stoichiometric ferroelectric thin film crystals with Bi incorporated therein reasonably and in a self-alignment manner.

Electron Device

After processed by semiconductor processes, the multilayer thin film of the invention may be applied to semiconductor memories constructed as capacitors and FET gates, thin-film ferroelectric devices such as infrared sensors, recording media for recording information by polarization reversal of ferroelectrics by AFM (atomic force microscope) probes or the like, thin-film vibrators such as FBARs, thin-film VCOs and thin-film filters used for mobile communications equipment, thin-film piezoelectric devices used for liquid injectors, and so on. Of these, thin-film vibrators such as FBARs, thin-film VCOs and thin-film filters are especially preferred.

Processing by semiconductor processes may be carried out either after or in the process of the formation of multilayer thin films. For instance, the buffer layer including an electrically conductive thin film is first formed. Then, the perovskite oxide thin film is formed on the buffer layer from which the conductive thin film is partially etched away or otherwise removed.

When removal of a part of the buffer layer is followed by the formation of the perovskite oxide thin film, the Si substrate is exposed at buffer layer-free sites. Alternatively, even when a part of the buffer layer remains intact, the surface properties of that part often become worse. In some cases, the perovskite oxide thin film formed at such sites is a non-expitaxial film or contains a pyrochlore phase. In such cases, it is required that the perovskite oxide thin film be epitaxially grown at sites where the buffer layer remains quite intact.

By using for the perovskite oxide thin film a material such as PbTiO₃ which allows perovskite structure crystals to occur more easily as compared with PZT, it is also possible to enhance the crystallographic properties of the ferroelectric thin film at sites free from the buffer layer or inhibit the formation of the pyrochlore phase.

### EXAMPLE

In what follows, the present invention is now explained in more details with reference the following some specific examples.

### Example 1

A multilayer thin film comprising an Si (100) single crystal substrate and, in order from the substrate, a ZrO₂ thin film, a Y₂O₃ thin film, a Pt thin film, a PbTiO₃ thin film and a PZT thin film stacked thereon was prepared in the following procedure.

First of all, an Si single crystal wafer (in a cylindrical form of 2 inches in diameter and 250 μm in thickness) cut with a surface defined by the (100) plane, followed by mirror polishing, was provided. This wafer was then washed on the surface with etching, using a 40% aqueous solution of ammonium fluoride.

Subsequently, the single crystal substrate 2 was fixed to the substrate holder 3 having rotating and heating mechanisms and housed in the vacuum chamber 1a in the evaporation system 1 shown in FIG. 1. After the vacuum chamber was evacuated to 10⁻⁶ Torr by means of an oil diffusion pump, the substrate was rotated at 20 rpm and heated to 600° C. while oxygen was introduced in the vicinity of the substrate at a rate of 25 cc/min. through the nozzle 8 for the purpose of protecting the washed surface of the substrate with an Si oxide. Consequently, the surface of the substrate was thermally oxidized to form an about 1 nm thick Si oxide film on the surface of the substrate.

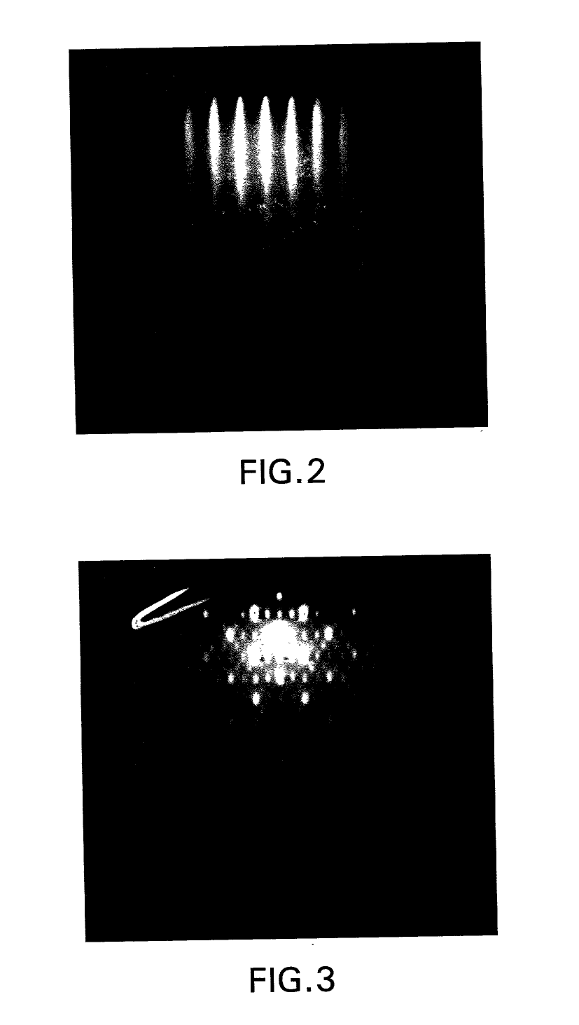

Next, the substrate was heated to 900° C. and rotated at 20 rpm. At this time, an oxygen gas was introduced at a rate of 25 cc/min. from the nozzle and metallic Zr was evaporated from the associated evaporation source to feed it onto the surface of the substrate for the reduction of the Si oxide formed at the previous step and the formation of a thin film. In this regard, the amount of metallic Zr fed was 10 nm as calculated on a ZrO₂ film thickness basis. The fact that this thin film was a (001) uniaxially oriented ZrO₂ thin film of high crystallographic properties was shown by the presence of a distinct (002) peak for ZrO₂ in X-ray diffraction. As shown in FIG. 2, the ZrO₂ thin film exhibits a RHEED image having a perfect streak pattern, indicating that this thin film has a flat surface on a molecular level and is an epitaxial film of high crystallographic properties.

Next, the single crystal substrate with the ZrO₂ thin film formed thereon was used as a fresh substrate. Metallic Y was fed onto the surface of the substrate under the conditions of a substrate temperature of 900° C., a substrate rpm of 20 and an oxygen gas feed rate of 15 cc/min., thereby forming a Y₂O₃ thin film thereon. The amount of metallic Y fed was 40 nm as calculated on a Y₂O₃ basis. As shown in FIG. 3, the RHEED image of this Y₂O₃ thin film exhibits sharp spots, indicating that the Y₂O₃ thin film is an epitaxial film of improved crystallographic properties, with surface asperities. Observation of a section of the Y₂O₃ thin film under a transmission electron microscope indicates the presence of 10 nm high facet planes at a ratio of 95% or higher.

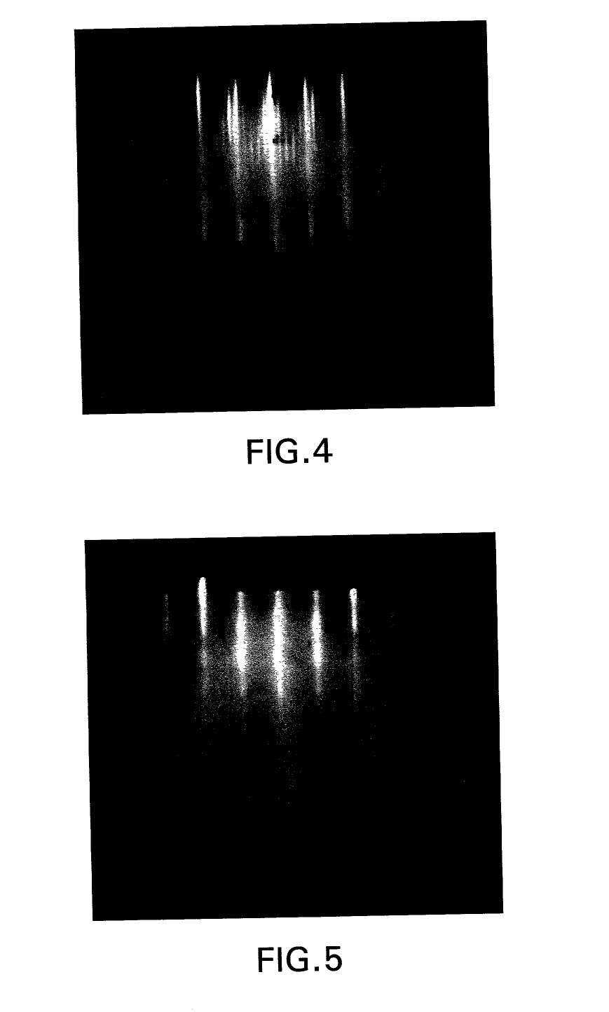

Next, a 100 nm thick Pt thin film was formed as the metal thin film on the Y₂O₃ thin film. The substrate temperature was 700° C. and the substrate rpm was 20. This Pt thin film exhibits a RHEED image having a sharp streak pattern as shown FIG. 4, indicating that the Pt thin film is an epitaxial film of improved crystallographic properties, with a flat surface on a molecular level.

As measured according to JIS B0610, the surface of the Pt thin film was found to have a ten-point average roughness Rz (at a reference length of 1,000 nm) of 1.1 to 1.8 nm, that is, direct evidence for improved flatness.

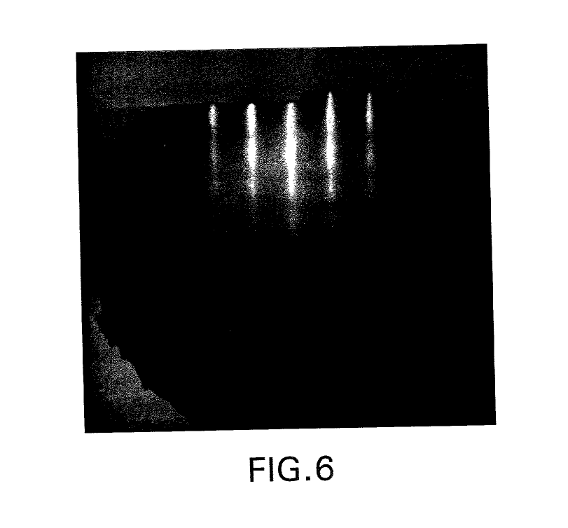

Next, a 30 nm thick PbTiO₃ film was formed on the Pt thin film. More specifically, the substrate was heated to 600° C. and rotated at 20 rpm. Then, a radical oxygen gas was introduced from an ECR oxygen source at a rate of 10 cc/min., and PbO and TiOₓ (x=1.67) were fed onto the substrate from the respective evaporation sources, so that the PbTiO₃ film was formed thereon. The amounts of the materials fed from their evaporation sources were controlled in such a way that the molar ratio for PbO:TiO₂ was 2:1. As shown in FIG. 5, the thus formed PbTiO₃ film exhibits a sharp streak pattern, indicating that it is an epitaxially grown film of satisfactory crystallographic properties. The formed PbTiO₃ film had a specific resistance of 2×10¹⁰ Ωcm.

In structural consideration of an electron device, it is acceptable to process the Pt thin film by partial etching into the desired size. In some cases, PbTiO₃ grows epitaxially on the Pt thin film in the cube-on-cube fashion and grows epitaxially at a Pt thin film free side yet at a 45° turned angle within the plane. At this time, PZT grows epitaxially with respect to the PbTiO₃ thin film. It follows that PZT grows epitaxially on the Pt thin film in the cube-on-cube fashion and grows epitaxially at the Pt thin film free site yet at a 45° turned angle within the plane.

Next, a 470 nm thick PZT film was formed on the PbTiO₃ thin film. While the substrate was heated to 600° C. and rotated at 20 rpm, a radical oxygen gas was introduced from an ECR oxygen source at a rate of 10 cc/min., and PbO, TiOₓ (x=1.67) and Zr were fed onto the substrate from the respective evaporation sources, so that the PZT film was formed thereon. The amounts of the materials fed from their evaporation sources were controlled in such a way that the molar ratio for PbO:ZrO₂:TiO₂ was 2:0.25:0.75.

X-ray fluorescence spectrometry of the composition (in atomic ratio) of the PZT film gave

Pb/(Ti+Zr)=1.00

Zr/Ti=0.330

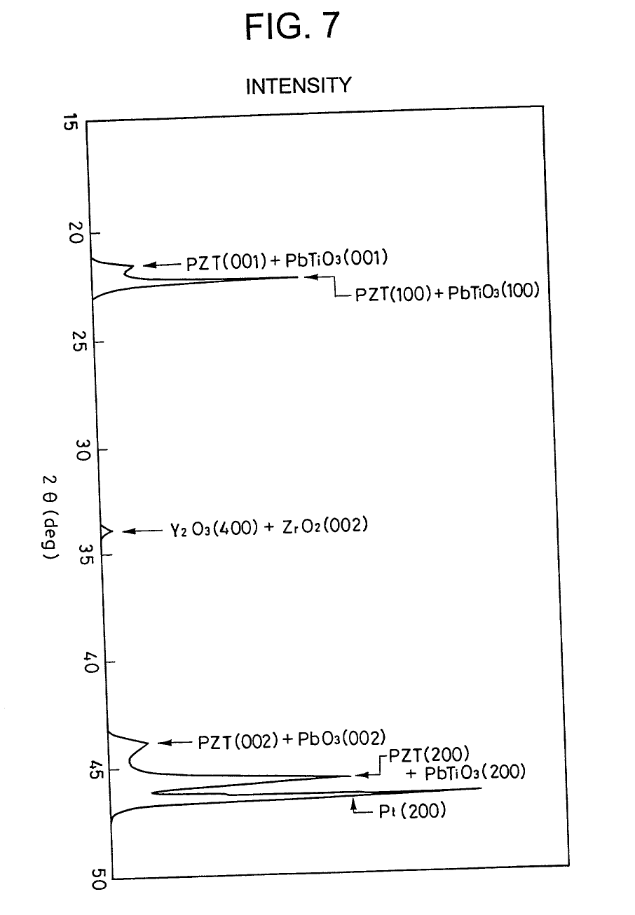

The thus formed PZT film exhibits a sharp streak pattern as shown in FIG. 6. As a result of measurement of X-ray diffraction of the multilayer thin film having a PZT/PbTiO₃/Pt/Y₂O₃/ZrO₂/Si (100) structure, only peaks equivalent to the (001) or (100) of each layer were observed, as shown in FIG. 7, indicating that this multilayer thin film is an epitaxially grown film of high crystallographic properties.

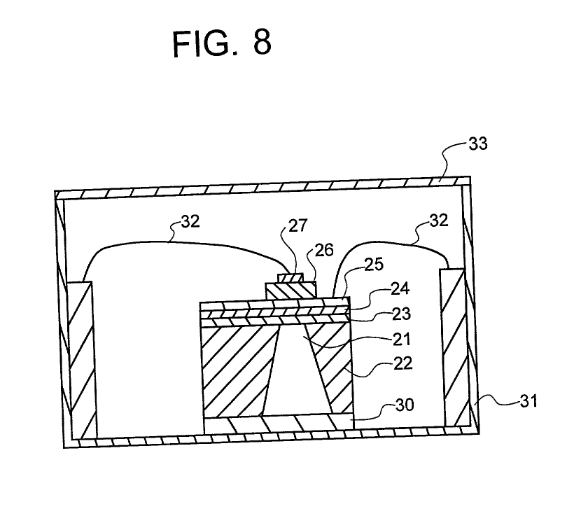

An FBAR device having the structure shown in FIG. 8 was prepared, using this multilayer thin film.

The FBAR device shown in FIG. 8 comprises an Si (100) single crystal substrate 22 having a via hole 21 (hereinafter called simply the Si substrate) and, in order from the Si substrate 22, a buffer layer 23 comprising an oxide thin film or the like, a lower electrode 24 comprising an electrically conductive thin film of Pt or the like, a perovskite oxide thin film 25 of PbTiO₃, etc., a ferroelectric thin film 26 of PZT or the like, and an upper electrode 27 comprising an electrically conductive thin film of Au or the like. The via hole 21 is formed by anisotropic etching of Si from the lower side shown in FIG. 8, and allows the thin films stacked thereon to set up a diaphragm structure. The lower side of the Si substrate 22 is bonded to the bottom of a package 31 by means of a die bonding agent 30, and the upper portion of the package 31 is tightly lidded at 33.

First of all, the buffer layer 23 of ZrO₂, and Y₂O₃, and the lower electrode 24 of Pt were formed on the Si (100) substrate 22 in this order. Then, the Pt layer 24 was partially etched away to subject the lower electrode to patterning, and the perovskite oxide thin film 25 of PbTiO₃ and then the PZT film 26 were formed thereon by evaporation. Here the Pt electrode has an area of 20 μm×20 μm. At this time, a part of the PbTiO₃ and PZT films was formed on Y₂O₃. However, it has been shown by RHEED that the PbTiO₃ and PZT films are grown epitaxially on both Pt and Y₂O₃. The PZT thin film had a composition of a Zr:Ti atomic ratio of 0.25:0.75 and a thickness of 500 nm. Subsequently, the Al upper electrode 27 having an electrode area of 20 μm×20 μm square was formed and patterned, and the via hole 21 was formed by etching the Si substrate 22. Finally, the multilayer thin film was divided into chips by a dicing device. Each chip was mounted in the package 31 using the die bonding agent 30, and a wire 32 was used for interconnection. The package was sealed by the lid 33 to obtain a complete device.

This FBAR device was first measured with no application of direct voltage to the PZT film. The resonant and anti-resonant frequencies were 2.2 GHz and 2.56 GHz, respectively. An impedance difference at the resonant and anti-resonant frequencies was 31 dB. In addition, a very excellent electromechanical coupling factor of k²=39% was obtained. These properties remained substantially unchanged even when different direct voltages were applied to the PZT film.

For the purpose of comparison, an FBAR device was prepared, using a multilayer thin film having a PZT/Pt/Y₂O₃/ZrO₂/Si (100) structure or a PbTiO₃ layer free structure. The mutilayer thin film and device were formed in the same manner as described with reference to those using the aforesaid PbTiO₃ layer.

As a result of measurement of this FBAR device, resonance and anti-resonance were hardly observed in the absence of direct voltage applied to the PZT film. Even at an applied direct voltage of 9 V, the impedance difference and electromechanical coupling factor were 20 dB and 33% at most, respectively, and so were inferior to those obtained with PbTiO₃.

From this, it is appreciated that the multilayer thin film of the present invention and the electron device using the same possess very excellent properties.

### EFFECT OF THE INVENTION

According to the present invention wherein a perovskite oxide thin film such as a PbTiO₃ thin film is first epitaxially grown on an Si (100) substrate, and a ferroelectric film such as a PZT film is then epitaxially grown on the perovskite oxide thin film, it is possible to obtain a ferroelectric film having improved properties on the Si (100) substrate and achieve its fabrication process.

When a pattern is formed by processing or removing the buffer layer by etching or the like, it is possible to enhance the crystallographic properties of the ferroelectric thin film or inhibit the formation of a pyrochlore phase at buffer layer-free sites by using for the perovskite oxide thin film a PbTiO₃ or other material capable of providing perovskite structure crystals more easily as compared with PZT.

After processed typically by semiconductor processes, the multilayer thin film of the present invention may be applied to various electron devices inclusive of semiconductor memories constructed as capacitors and FET gates, thin-film ferroelectric devices such as infrared sensors, recording media for recording information by polarization reversal of ferroelectrics by AFM (atomic force microscope) probes or the like, thin-film vibrators such as FBARs, thin-film VCOs and thin-film filters used for mobile communications equipment and thin-film piezoelectric devices used for liquid injectors.

What we claim is:

1. A multilayer thin film formed on an Si substrate by epitaxial growth, which comprises:
a buffer layer formed on said Si substrate, which layer includes an oxide thin film,
a perovskite oxide thin film formed on said buffer layer, which film has a (100) or (001) orientation, and
a ferroelectric thin film epitaxially grown on said perovskite oxide thin film.

2. The multilayer thin film of claim 1, wherein said perovskite oxide thin film has insulating properties.

3. The multilayer thin film of claim 1, which has an electrically conductive thin film between said perovskite oxide thin film and said oxide thin film in said buffer layer.

4. The multilayer thin film of claim 1, wherein said perovskite oxide thin film comprises PbTiO₃.

5. The multilayer thin film of claim 1, wherein said ferroelectric oxide thin film comprises PZT.

6. An electron device comprising a multilayer thin film as recited in claim 1.

7. A multilayer thin film fabrication process by:
forming a buffer layer including an oxide thin film on an Si (100) substrate,
epitaxially growing a perovskite oxide thin film having a (100) or (001) orientation on said buffer layer, and
epitaxially growing a ferroelectric thin film on said perovskite oxide thin film.
